(19) United States
(12) Patent Application Publication
(10) Pub. No.: US 2009/0280587 A1
(43) Pub. Date: Nov. 12, 2009

(54) METHOD OF TREATING SODA-LIME GLASS SUBSTRATE AND METHOD OF MANUFACTURING A DISPLAY SUBSTRATE USING THE SAME

(76) Inventors: Sang-Woo WHANGBO, Seoul (KR); Bong-Kyu Shin, Bucheon-si (KR); Sang-Uk Lim, Suseong-gu (KR); Jun-Hyung Souk, Suji-gu (KR); Jin-Ho Ju, Seoul (KR)

Correspondence Address: F. CHAU & ASSOCIATES, LLC, 130 WOODBURY ROAD, WOODBURY, NY, 11797, US

(21) Appl. No.: 12/427,996

(22) Filed: Apr. 22, 2009

(30) Foreign Application Priority Data
May 9, 2008 (KR) 2008-43508

(51) Int. Cl. H01L 33/00; B08B 5/00; B05D 3/10

(52) U.S. Cl. 438/22; 134/1.1; 427/534; 257/E33.001

(57) ABSTRACT

A method of treating a soda-lime glass (SLG) substrate includes cleaning the SLG substrate using an alkali cleaning solution and cleaning the cleaned SLG substrate using a plasma process. The SLG substrate is cleaned using the alkali cleaning solution to remove particles adhered to the SLG substrate. Thus, defects due to the adhering particles may be reduced.

### PRIORITY STATEMENT

This application claims priority under 35 U.S.C. §119 to Korean Patent Application No. 2008-43508, filed on May 9, 2008, the disclosure of which is hereby incorporated by reference herein in its entirety.

### BACKGROUND OF THE INVENTION

1. Technical Field

The present disclosure relates to a method of treating a soda-lime glass (SLG) substrate and to a method for manufacturing a display substrate using the method of treating the SLG substrate.

2. Description of the Related Art

In a liquid crystal display (LCD) apparatus, an image may be displayed by applying a voltage to a liquid crystal layer interposed between two glass substrates and controlling light transmissivity. Generally, borosilicate glass substrates are used for the glass substrates. A borosilicate glass substrate may have high resistance against thermal shock, rapid temperature variation and chemical corrosion. However, the price of the borosilicate glass substrate may be high so that the borosilicate glass substrate may make up a large portion of the cost of materials for the LCD apparatus.

On the other hand, a soda-lime glass (SLG) substrate may be cheaper, and may have high resistance to corrosive compounds because the SLG substrate is an oxide mixture including silica, calcium, sodium and so on. However, the SLG substrate may be warped in a high-temperature process, so that the surface uniformity of a thin film may be deteriorated. In addition, the SLG substrate may also have a difficulty in that alkali ions, such as the sodium, may flow into the thin film from the SLG substrate so that device characteristics of the product may be deteriorated or the reliability of the product may be reduced. Accordingly, the SLG substrate may be difficult to apply to the LCD apparatus.

However, the demand for large-sized LCD apparatuses is rapidly increasing, and thus a technique for applying the cheaper SLG substrate to the LCD apparatus instead of the more expensive borosilicate glass substrate may be required to enhance price competitiveness.

### SUMMARY OF THE INVENTION

Exemplary embodiments of the present invention may provide a method of treating a soda-lime glass (SLG) substrate to enhance reliability.

Exemplary embodiments of the present invention may provide a method for manufacturing the display substrate using the method of treating the soda-lime glass (SLG) substrate.

In accordance with an exemplary embodiment of the present invention, a method of treating a soda-lime glass (SLG) substrate is provided. The method includes cleaning the SLG substrate using an alkali cleaning solution and cleaning the cleaned SLG substrate using a plasma process.

The alkali cleaning solution includes an alkali material having a concentration of about 1% to about 25%. The alkali material may include at least one of potassium hydroxide (KOH) and sodium hydroxide (NaOH). The plasma process may use one among nitrogen gas (N₂), ammonia gas (NH₃) and hydrogen gas (H₂).

In accordance with an exemplary embodiment of the present invention, a method for manufacturing a display substrate is provided. The method includes cleaning a surface of a soda-lime glass (SLG) substrate using an alkali cleaning solution, forming a barrier layer on the cleaned SLG substrate, forming a gate line on the SLG substrate on which the barrier layer is formed. The method further includes forming a data line on the SLG substrate on which the gate line is formed and forming a pixel electrode on the SLG substrate on which the the data line is formed.

In accordance with another exemplary embodiment of the present invention, a method of manufacturing a display substrate is provided. The method includes cleaning a surface of a soda-lime glass (SLG) substrate using an alkali cleaning solution, cleaning the cleaned SLG substrate using a plasma process, forming a barrier layer on the cleaned SLG substrate, forming a first conductive layer on the barrier layer, patterning the first conductive layer to form a first conductive pattern, wherein the first conductive pattern includes a gate line GL, a gate electrode GE and a storage line STL. The method further includes forming a gate insulation layer on the SLG substrate on which the first conductive pattern is formed, forming a channel layer on the SLG substrate on which the gate insulation layer is formed, wherein the channel layer includes a semiconductor layer and an ohmic contact layer, forming a second conductive layer on the SLG substrate on which the channel layer is formed, patterning the second conductive layer and the channel layer to form a second conductive pattern and the channel layer under the second conductive pattern, wherein the second conductive pattern includes a data line DL, a source electrode SE and a drain electrode DE and forming a protective layer on the SLG substrate on which the second conductive pattern is formed. Moreover, the method further includes etching the protective layer to form contact hole C exposing the drain electrode DE, forming a transparent conductive layer on the SLG substrate on which the contact hole C is formed and patterning the transparent conductive layer to form a third conductive pattern including the pixel electrode.

According to exemplary embodiments of the present invention, an SLG substrate is cleaned using an alkali cleaning solution to remove particles adhered to the SLG substrate. Thus, defects due to the adhering particles may be reduced.

### BRIEF DESCRIPTION OF THE DRAWINGS

Exemplary embodiments of the present invention can be understood in more detail from the following detailed description taken in conjunction with the accompanying drawings, in which:

FIG. 1 is a plan view illustrating a display substrate according to an exemplary embodiment of the present invention;

FIG. 2 is a cross-sectional view taken along a line I-I′ in FIG. 1;

FIGS. 3A to 3E are cross-sectional views illustrating a process for manufacturing the display substrate in FIG. 2;

FIG. 4A is a defect detection image related to a display substrate to which a cleaning process has not been applied;

FIG. 4B is an enlarged image showing a defect in FIG. 4A;

FIG. 5A is a defect detection image related to a display substrate undergoing a cleaning process;

FIG. 5B is an enlarged image showing a defect in FIG. 5A;

FIG. 6 is a graph illustrating the number of defects due to a display substrate undergoing a plasma pre-treatment process;

FIG. 7A is a graph illustrating the surface stress of a display substrate according to various materials; and

FIG. 7B is a defect detection image related to a display substrate of sample 3 in FIG. 7A.

### DETAILED DESCRIPTION OF THE EXEMPLARY EMBODIMENTS OF THE INVENTION

The invention is described more fully hereinafter with reference to the accompanying drawings, in which exemplary embodiments of the invention are shown. This invention may, however, be embodied in many different forms and should not be construed as limited to the exemplary embodiments set forth herein. In the drawings, the size and relative sizes of layers and areas may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, areas, layers and/or sections, these elements, components, areas, layers and/or sections should not be limited by these terms. These terms are only used to distinguish one element, component, area, layer or section from another area, layer or section. Thus, a first element, component, area, layer or section discussed below could be termed a second element, component, area, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of areas illustrated herein but are to include deviations in shapes that result, for example, from manufacturing. For example, an implanted area illustrated as a rectangle will, typically, have rounded or curved features and/or a gradient of implant concentration at its edges rather than a binary change from implanted to non-implanted area. Likewise, a buried area formed by implantation may result in some implantation in the area between the buried area and the surface through which the implantation takes place. Thus, the areas illustrated in the figures are schematic in nature and their shapes are not intended to illustrate the actual shape of an area of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be explained in detail with reference to the accompanying drawings.

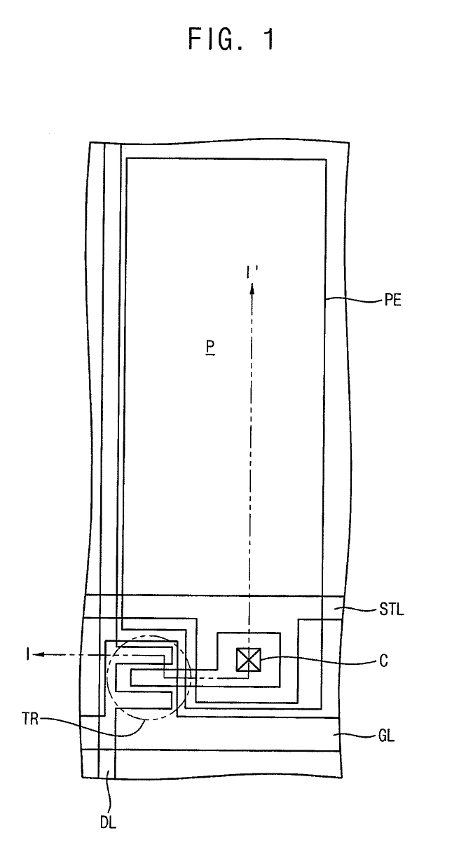

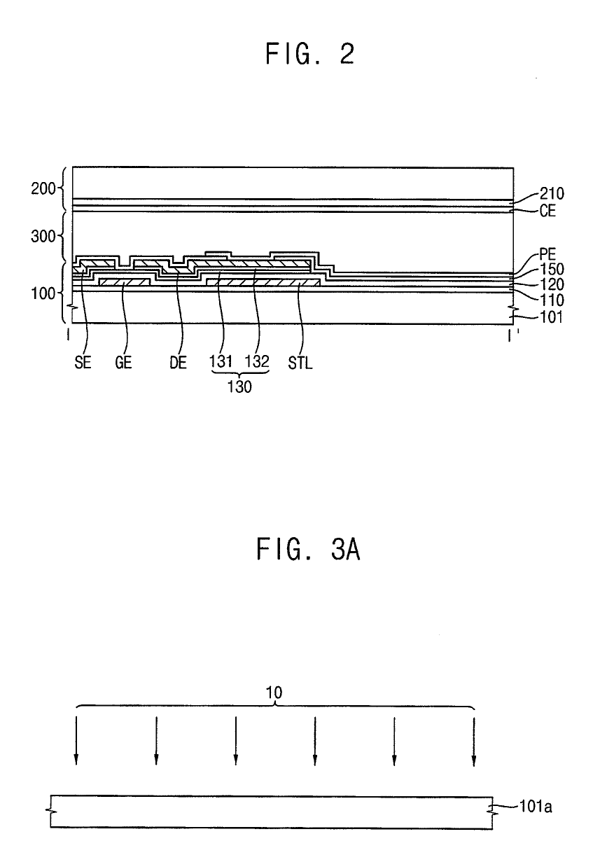

FIG. 1 is a plan view illustrating a display substrate according to an exemplary embodiment of the present invention. FIG. 2 is a cross-sectional view taken along a line I-I′ in FIG. 1.

Referring to FIGS. 1 and 2, the display panel includes a first display substrate 100, a second display substrate 200 and a liquid crystal layer 300.

The first display substrate 100 includes soda-lime glass (SLG) 101. The SLG 101 is an alkali glass substrate.

A barrier layer 110, a gate line GL, a gate electrode GE, a storage line STL, a gate insulation layer 120, a channel layer 130, a data line DL, a source electrode SE, a drain electrode DE, a protective layer 150 and a pixel electrode PE are formed on the SLG substrate 101.

The barrier layer 110 is disposed between the SLG substrate 101 and a conductive pattern disposed on the SLG substrate 101 to enhance the adhesive strength of the SLG substrate 101 and the conductive pattern. For example, the conductive pattern may include a gate line GL, a gate electrode GE, and a storage line STL. An alkali ion emitted from the SLG substrate 101 reacts with water and organic matter in air to form adhering particles on the surface of the SLG substrate 101.

The adhering particles may be separated from the conductive pattern and the SLG substrate 101, or shorted with the conductive pattern. Thus, the barrier layer 110 is disposed between the SLG substrate 101 and the conductive pattern.

The barrier layer 110 may be formed by, for example, a transparent material having a thickness of about 50 Å to about 2,000 angstroms (Å). The transparent material may be, for example, silicon oxide (SiOx), silicon nitride (SiNx), etc. For example, the silicon nitride (SiNx) may be formed at a low temperature of about 200° C. to about 300° C.

A plurality of gate lines is extended in a first direction to dispose on the SLG substrate 101. The gate electrode GE may be defined on a gate line GL, or protruded from the gate line GL. The storage line STL may be disposed in an area adjacent the gate line GL to parallel with the gate line GL, or disposed in an area adjacent the data line DL to parallel with the data line DL. The storage line STL is overlapped with the pixel electrode disposed in a pixel area P to define a storage capacitor.

The gate insulation layer 120 is disposed on the SLG substrate having the conductive pattern that includes the gate line GL, the gate electrode GE and the storage line STL to cover the conductive pattern.

The channel layer 130 is disposed on the gate insulation layer 120 corresponding to an area in which the gate electrode GE is disposed. The channel layer 130 includes a semiconductor layer 131 doped with impurities and an ohmic contact layer 132 disposed between a source electrode SE and the semiconductor layer 131 for decreasing contact resistance. The ohmic contact layer 132 is disposed between a drain electrode DE and the semiconductor layer 131.

A plurality of data lines is extended in a second direction crossing the first direction to be disposed on the SLG substrate 101. The source electrode SE is defined on a portion of the data line DL to be overlapped with the gate electrode GE. Otherwise, the source electrode SE is protruded toward the gate electrode GE from the data line DL to be overlapped with the gate electrode GE.

The drain electrode DE is spaced apart from the source electrode SE, and is overlapped with the gate electrode GE. A switching element TR connected to the gate line GL and the data line DL may include the gate electrode GE, the source electrode SE, the drain electrode DE and the channel layer 130.

The protective layer 150 is disposed on the SLG substrate 101 having the switching element TR. The protective layer 150 may have, for example, a double-layer structure comprising a passivation layer and an organic layer, or a single layer comprising the passivation layer.

The pixel electrode PE is disposed on the protective layer 150 corresponding to the pixel area to contact with the drain electrode DE through the contact hole C. The pixel electrode PE comprises, for example, a transparent material. An alignment layer may be disposed on the pixel electrode PE to align the liquid crystal layer 300.

The second display substrate 200 is opposite to the first display substrate 100 to be coupled with the first display substrate 100. The second display substrate 200 includes a color filter layer 210 and a common electrode CE.

The color filter layer 210 is disposed in a corresponding area in which the pixel electrode PE is formed. Herein, the second display substrate 200 includes the color filter layer 210, but the first display substrate 100 may include the color filter layer 210. For example, the color filter layer 210 may be disposed between the pixel electrode PE and the protective layer 150 of the first display substrate 100.

The common electrode CE is disposed on the color filter layer 210 to define a liquid crystal capacitor comprising the pixel electrode PE, the liquid crystal layer 300 and the common electrode CE.

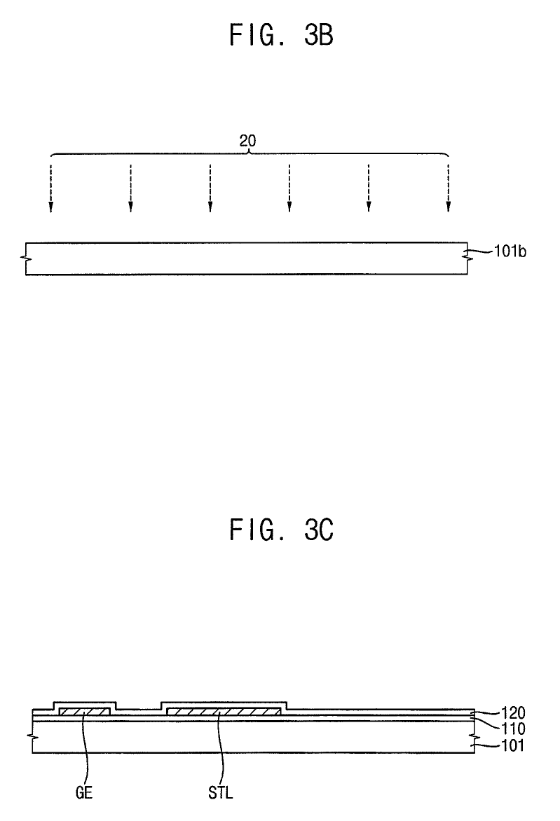

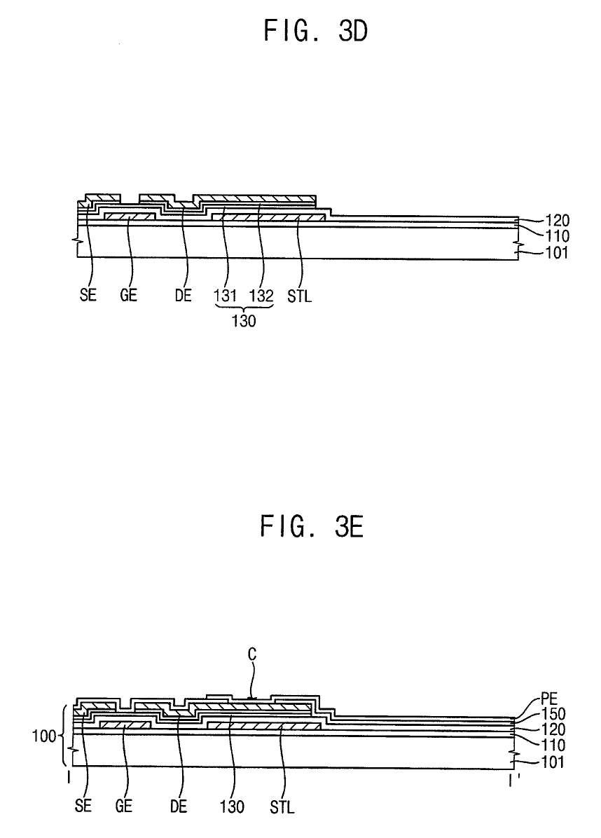

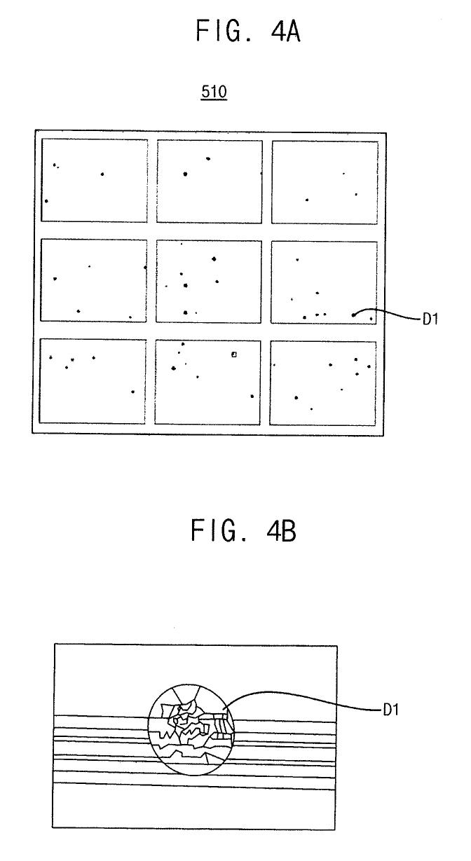

FIGS. 3A to 3E are cross-sectional views illustrating a process for manufacturing the display substrate in FIG. 2.

Referring to FIGS. 1 and 3A, an initial SLG substrate 101a is cleaned using an alkali cleaning solution 10. The alkali cleaning solution 10 includes an alkali material. For example, the alkali material may include potassium hydroxide (KOH), sodium hydroxide (NaOH), etc. The alkali material may include, for example, at least one of potassium hydroxide (KOH) and sodium hydroxide (NaOH).

The alkali cleaning solution 10 may remove adhering particles adhered to the surface of the initial SLG substrate 101a. The cleaning effectiveness increases as the concentration of the alkali material included in the alkali cleaning solution 10 increases. Also, the cleaning effectiveness increases as the number of cleanings increases. For example, the concentration of the alkali material included in the alkali cleaning solution 10 may be about 1% to about 25%.

Referring to FIGS. 1 and 3B, a SLG substrate 101b cleaned by the alkali cleaning solution undergoes a plasma pre-treatment process. The plasma pre-treatment process removes the adhering particles remaining on the surface of the SLG substrate 101b, reduces the activity of the adhering particles to reduce defects in following processes.

The plasma pre-treatment process uses a reaction gas. The reaction gas may include, for example, nitrogen gas (N₂), ammonia gas (NH₃), hydrogen gas (H₂), etc. For example, the plasma pre-treatment process may use nitrogen gas (N₂).

Referring to FIGS. 1 and 3C, the barrier layer 110 is formed on the SLG substrate 101 removed the adhering particles by the cleaning and pre-treatment processes.

The barrier layer 110 may be formed from, for example, the transparent material. The thickness of the barrier layer 110 may be, for example, about 50 Å to about 2,000 Å. The transparent material may include silicon oxide (SiOx), silicon nitride (SiNx), etc. For example, the silicon nitride (SiNx) may be formed at a low temperature of about 200° C. to about 300° C.

A first conductive layer is formed on the barrier layer 110. The first conductive layer may include, for example, at least one of chromium (Cr), chromium (Cr) alloy, molybdenum (Mo), molybdenum nitride (MoN), molybdenum niobium (MoNb), molybdenum (Mo) alloy, copper (Cu), copper (Cu) alloy, copper-molybdenum (CuMo) alloy, aluminum (Al), aluminum (Al) alloy, silver (Ag) and silver (Ag) alloy. The first conductive layer is patterned to form a first conductive pattern. The first conductive pattern includes the gate line GL, the gate electrode GE and the storage line STL.

The gate insulation layer 120 is formed on the SLG substrate 101 on which the first conductive pattern is formed.

Referring to FIGS. 1 and 3D, the channel layer 130 is formed on the SLG substrate 101 on which the gate insulation layer 120 is formed. The channel layer 130 includes the semiconductor layer 131 and the ohmic contact layer 132. For example, the semiconductor layer 131 is an n⁺ ion-doped layer (a-Si n⁺), and the ohmic contact layer 132 is an amorphous silicon layer (a-Si).

A second conductive layer is formed on the SLG substrate 101 on which the channel layer 130 is formed. The second conductive layer may be, for example, a metal material including at least one of molybdenum (Mo), molybdenum nitride (MoN), molybdenum niobium (MoNb), molybdenum (Mo) alloy, copper (Cu), copper (Cu) alloy, copper-molybdenum (CuMo) alloy, aluminum (Al), aluminum (Al) alloy, silver (Ag) and silver (Ag) alloy. The second conductive layer is patterned a second conductive pattern. The second conductive pattern includes the data line DL, the source electrode SE and the drain electrode DE.

The channel layer 130 and the second conductive layer 120 are patterned using one mask to form the channel layer 130 under the second conductive pattern. However, the channel layer 130 and the second conductive layer 120 is patterned using different masks, so that the channel layer 130 may be formed on the gate insulation layer 110 corresponding to an area in which the gate electrode GE is formed.

Referring to FIGS. 1 and 3E, the protective layer 150 is formed on the SLG substrate 101 on which the second conductive pattern is formed. The protective layer 150 may have, for example, a double-layer structure comprising a passivation layer and a thick organic layer, or a single layer comprising the passivation layer. The SLG substrate 101 on which the protective layer 150 is formed in a contact hole C

The protective layer 150 is etched using an etching process to form the contact hole C exposing the drain electrode DE. The transparent conductive layer is formed on the SLG substrate 101 on which the contact hole C is formed. The transparent conductive layer is patterned to form a third conductive pattern including the pixel electrode PE. For example, the third conductive layer 170 may include the transparent conductive material such as IZO, ITO and a-ITO.

Hereinafter, effects of improving the defects of the display substrate of the present exemplary embodiment will be explained.

First, the effect of cleaning according to the alkali cleaning solution will be explained.

A plurality of defects were detected from the display substrate employed the SLG substrate un-cleaning by the alkali cleaning solution, and the display substrate employed the SLG substrate cleaning by the alkali cleaning solution, respectively.

FIG. 4A is a defect detection image related to a display substrate to which a cleaning process has not been applied. FIG. 4B is an enlarged image showing a defect in FIG. 4A. As shown FIG. 4A, the defects D1 were detected in the display substrate 510. As shown FIG. 4B, the defects D1 were a cracked metal line and an opened metal line.

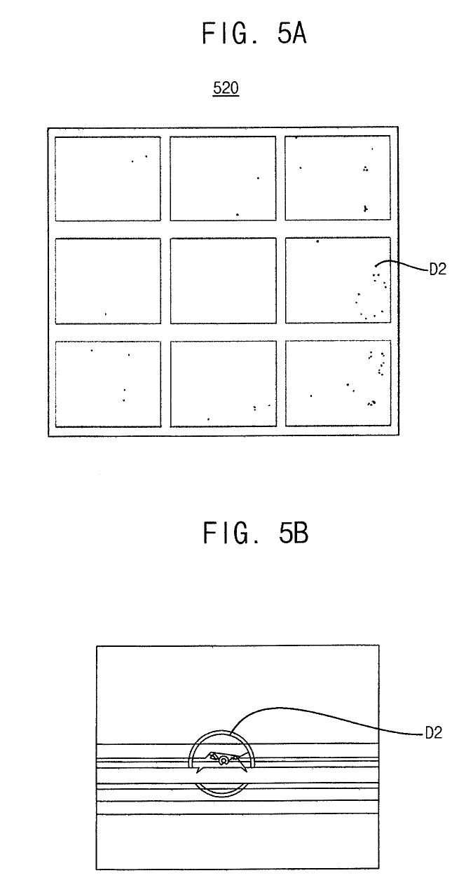

FIG. 5A is a defect detection image related to a display substrate to which a cleaning process has been applied. FIG. 5B is an enlarged image showing a defect in FIG. 5A. As shown FIG. 5A, the defects D2 were detected in the display substrate 520. But, the defects D2 of the display substrate 520 were effectively reduced comparison to the defects D1 of the display substrate 510 as shown FIG. 4A.

In addition, the size of the defect D2 as shown FIG. 5B was smaller in comparison with the size of the defects D1 as shown FIG. 4B.

Table 1 shows the number of the defects generated in the display substrate according to the concentration of potassium hydroxide (KOH) included in the alkali cleaning solution and the times of the cleaning using the alkali cleaning solution.

TABLE 1

| | KOH (about 1%), | KOH (about 5%), |
|---|---|---|
| | cleaning (1 time) | cleaning (2 times) |
| Number | 42 | 7 |
| of defects | | |

Referring to Table 1, in the display substrate cleaned one time by the alkali cleaning solution included the alkali material, for example, potassium hydroxide (KOH) of about 1%, 42 defects were detected. In, the display substrate cleaned two times by the alkali cleaning solution included potassium hydroxide (KOH) of about 5%, 7 defects were detected. Thus, the number of the defects was reduced the larger the concentration of potassium hydroxide (KOH) and the more times of cleaning.

Otherwise, the cleaning effectiveness may be the same even though the concentration of sodium hydroxide (NaOH) is increased.

Second, the effect of reducing defects due to the plasma pre-treatment process will be explained.

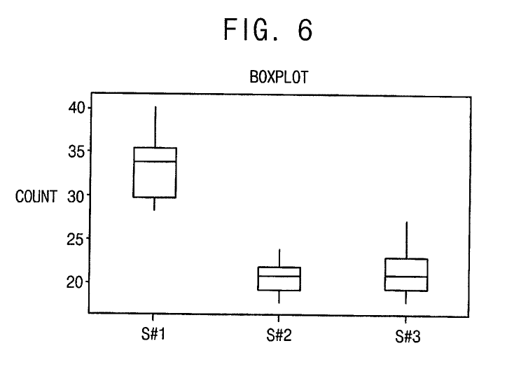

FIG. 6 is a graph illustrating the number of defects due to a display substrate undergoing a plasma pre-treatment process.

Referring to FIG. 6, a display substrate of sample 1 S#1 employing the SLG substrate to which the plasma pre-treatment process has not been applied. A display substrate of sample 2 S#2 is employed the SLG substrate undergoes the plasma pre-treatment process using nitrogen gas (N₂) for 30 seconds (s). A display substrate of sample 3 S#3 is employed the SLG substrate undergoes the plasma pre-treatment process using nitrogen gas (N₂) for 60 s.

In the display substrate of sample 1 S#1, about 30 to about 35 defects were generated. In the display substrate of sample 2 S#2, about 17 to about 21 defects were generated. In the display substrate of sample 3 S#3, about 18 to about 23 defects were generated.

Thus, cases in which the plasma pre-treatment process was performed had a reduced incidence of defects. However, the incidence of the defects was unrelated to increasing the time of the plasma pre-treatment process.

Third, the degree of defects according to materials of the barrier layer will be explained.

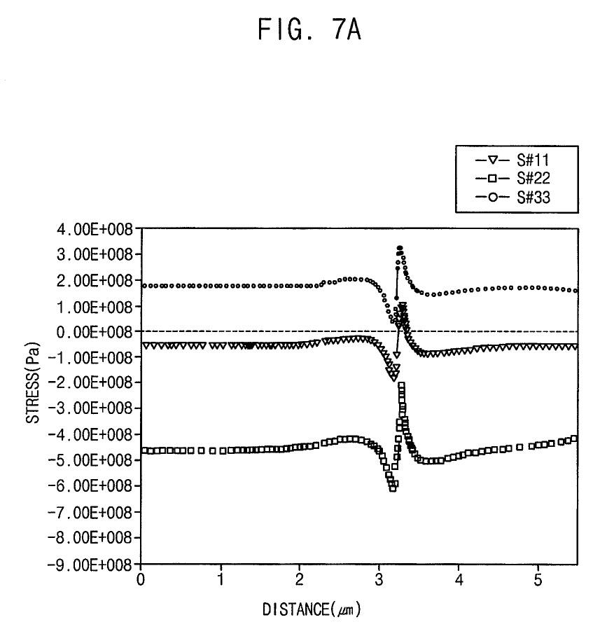

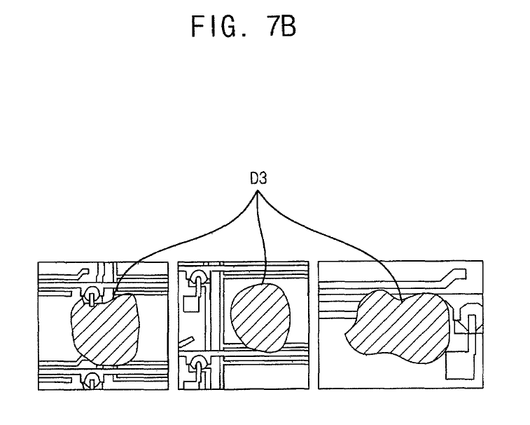

FIG. 7A is a graph illustrating the surface stress of a display substrate according to various materials.

Referring to FIG. 7A, a display substrate of sample 1 S#11 includes the barrier layer comprising silicon oxide (SiOx). A display substrate of sample 2 S#22 includes the barrier layer comprising silicon nitride (SiNx) formed at a low temperature of about 250° C. A display substrate of sample 3 S#33 includes the barrier layer comprising silicon nitride (SiNx).

When initial stress of the SLG substrates employed samples 1, 2 and 3 S#11, S#22 and S#33 was set to “0” (Pa), the display substrate of sample 1 S#11 approached the initial stress “0” (Pa). The display substrate of sample 2 S#22 had low compressive stress. The display substrate of sample 3 S#33 had high tensile stress.

FIG. 7B is a defect detection image related to a display substrate of sample 3 in FIG. 7A.

Referring to FIG. 7B, the display substrate of sample 3 S#33 having the high tensile stress generated a plurality of defects D3. The defects D3 decrease adhesion between the barrier layer and the SLG substrate to lift off the barrier layer.

Thus, when the silicon oxide (SiOx) is stressed by the stress substantially the same as the initial stress, the defect D3 was not generated. In addition, although the silicon nitride (SiNx) having the low compressive stress has a larger stress than the silicon oxide (SiOx), the defects were decreased.

According to exemplary embodiments of the present invention, an SLG substrate is cleaned using an alkali cleaning solution to remove particles adhered to the SLG substrate. Thus, the effect of cleaning of the SLG substrate may be improved.

In addition, the SLG substrate undergoes a plasma pre-treatment process before forming a barrier layer to reduce the activity of the adhering particles and to remove the adhering particles. Thus, the adhering particles may be removed by the cleaning and pre-treatment processes, so that defects of a metal line such as an opening and lifting may be prevented. In addition, the barrier layer may be formed by silicon oxide (SiOx) or silicon nitride (SiNx) in a low-temperature process to prevent a defect of the barrier layer peeling off from the SLG substrate.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A method of treating a soda-lime glass (SLG) substrate comprising:
cleaning the SLG substrate using an alkali cleaning solution; and
cleaning the cleaned SLG substrate using a plasma process.

2. The method of claim 1, wherein the alkali cleaning solution includes an alkali material having concentration of about 1% to about 25%.

3. The method of claim 1, wherein the alkali material includes at least one selected from the group consisting of potassium hydroxide (KOH) and sodium hydroxide (NaOH).

4. The method of claim 1, wherein the plasma process uses at least one gas selected from the group consisting of nitrogen gas (N₂), ammonia gas (NH₃) and hydrogen gas (H₂).

5. The method of claim 1, further comprising forming a barrier layer on the SLG substrate cleaned by the plasma process.

6. The method of claim 5, wherein the barrier layer comprises silicon oxide (SiOx).

7. The method of claim 5, wherein the barrier layer comprises silicon nitride (SiNx) and wherein the barrier layer is formed using a low-temperature process.

8. The method of claim 7, wherein a temperature of the low-temperature process is about 200° C. to about 300° C.

9. A method of manufacturing a display substrate comprising:
cleaning a surface of a soda-lime glass (SLG) substrate using an alkali cleaning solution;
forming a barrier layer on the cleaned SLG substrate;
forming a gate line on the SLG substrate on which the barrier layer is formed;
forming a data line on the SLG substrate on which the gate line is formed; and
forming a pixel electrode on the SLG substrate on which the data line is formed.

10. The method of claim 9, wherein the alkali cleaning solution includes an alkali material having concentration of about 1% to about 25%.

11. The method of claim 10, wherein the alkali material includes at least one selected from the group consisting of potassium hydroxide (KOH) and sodium hydroxide (NaOH).

12. The method of claim 9, wherein the plasma process uses at least one gas selected from the group consisting of nitrogen gas (N₂), ammonia gas (NH₃) and hydrogen gas (H₂).

13. The method of claim 12, further comprising forming a barrier layer on the SLG substrate cleaned by the plasma process.

14. The method of claim 9, wherein the barrier layer comprises silicon oxide (SiOx).

15. The method of claim 9, wherein the barrier layer comprises silicon nitride (SiNx) and wherein the barrier layer is formed using a low-temperature process.

16. The method of claim 15, wherein a temperature of the low-temperature process is about 200° C. to about 300° C.

17. The method of claim 9, further comprising forming a switching element connected to the gate line and the data line, the switching element including a gate electrode connected to the gate line, a source electrode connected to the data line, and a drain electrode being spaced apart from the source electrode.

18. The method of claim 17, further comprising forming a protective layer formed on the SLG substrate having the switching element, the pixel electrode contact with the drain electrode through a contact hole formed in the protective layer.

19. The method of claim 5, wherein the barrier layer is formed from a transparent material and wherein the barrier layer has a thickness of about 50 Å to about 100 Å.

20. A method of manufacturing a display substrate comprising:
cleaning a surface of a soda-lime glass (SLG) substrate using an alkali cleaning solution;
cleaning the cleaned SLG substrate using a plasma process;
forming a barrier layer on the cleaned SLG substrate;
forming a first conductive layer on the barrier layer;
patterning the first conductive layer to form a first conductive pattern, wherein the first conductive pattern includes a gate line GL, a gate electrode GE and a storage line STL;
forming a gate insulation layer on the SLG substrate on which the first conductive pattern is formed;
forming a channel layer on the SLG substrate on which the gate insulation layer is formed, wherein the channel layer includes a semiconductor layer and an ohmic contact layer;
forming a second conductive layer on the SLG substrate on which the channel layer is formed;
patterning the second conductive layer and the channel layer to form a second conductive pattern and the channel layer under the second conductive pattern, wherein the second conductive pattern includes a data line DL, a source electrode SE and a drain electrode DE;
forming a protective layer on the SLG substrate on which the second conductive pattern is formed;
etching the protective layer to form contact hole C exposing the drain electrode DE,
forming a transparent conductive layer on the SLG substrate on which the contact hole C is formed; and
patterning the transparent conductive layer to form a third conductive pattern including the pixel electrode.
